(19) United States
(12) Patent Application Publication
(10) Pub. No.: US 2006/0030119 A1
(43) Pub. Date: Feb. 9, 2006

(54) Method of manufacturing semiconductor device

(76) Inventors: Satoshi Onai, Gunma (JP); Toshihiro Okuda, Gunma (JP)

Correspondence Address: FISH & RICHARDSON P.C., P.O. BOX 1022, MINNEAPOLIS, MN, 55440-1022, US

(21) Appl. No.: 11/184,262

(22) Filed: Jul. 18, 2005

(30) Foreign Application Priority Data
Aug. 6, 2004 (JP) P2004-230638

(51) Int. Cl. H01L 21/76

(52) U.S. Cl. 438/424

(57) ABSTRACT

There has heretofore been a problem that a junction leak current between a collector and a base is generated by a crystal defect caused in an end portion of a groove adjacent to a base region. In the present invention, an opening is formed in a silicon oxide film and a TEOS film so as to have a distance from an upper end portion of a groove. Thereafter, a base extraction electrode is formed by utilizing the opening. Subsequently, an external base region is formed by solid phase diffusion from the base extraction electrode. In this event, there is secured a distance between the external base region and the upper end portion of the groove. By use of the manufacturing method described above, it is possible to suppress generation of a junction leak current between a collector and a base.

### BACKGROUND OF THE INVENTION

1. Field of the Invention

The present invention relates to a technology of preventing a junction leak current between a collector and a base by use of a STI method.

2. Description of the Related Art

In a conventional method of manufacturing a semiconductor device, there is a technology of realizing flatness and miniaturization of a surface of a semiconductor layer by use of a STI (shallow trench isolation) method instead of a LOCOS (local oxidation of silicon) method. In the STI method, a groove formed by means of dry etching is filled with an insulating film, and a trench is formed from an upper surface of the insulating film. Thereafter, a thermal oxide film is formed on an inner wall of the trench, and, by use of a CVD (chemical vapor deposition) method, the trench is filled with a CVI) oxide film. Subsequently, a base region is formed so as to be adjacent to the groove, and a polysilicon layer electrically connected to the base region is formed on the CVD oxide film. This technology is described for instance in Japanese Patent Application Publication No. Hei 9-8119 (p. 7 to 9, FIGS. 1 to 10).

As described above, in the conventional method of manufacturing a semiconductor device, after a groove is formed by etching an epitaxial layer by use of an RIE method, the groove is filled with a silicon oxide film formed by use of a thermal oxidation method and a silicon oxide film formed by use of the CVD method. Subsequently, after a base region is formed so as to be adjacent to an end portion of the groove, a polysilicon layer to be a base electrode is formed on the end portion of the groove. Particularly, in the end portion of the groove, a crystal defect is likely to be caused by a stress such as a thermal stress in the subsequent step. Thus, there is a problem that the crystal defect causes a junction leak current between a collector and a base. Moreover, there is a problem that, depending on a degree of the crystal defect, a PN junction between the collector and the base is destroyed and a leak current between the collector and an emitter is generated.

### SUMMARY OF THE INVENTION

The present invention is made in consideration of the foregoing circumstances. A method of manufacturing a semiconductor device of the present invention includes the steps of: forming a first insulating film on a semiconductor layer, the first insulating film having a first opening provided in a desired region, and forming a groove in the semiconductor layer through the first opening; partially removing the first insulating film so as to expose an upper end portion of the semiconductor layer from a region adjacent to the groove; etching the semiconductor layer so as to remove the upper end portion of the semiconductor layer by use of the first insulating film as an etching resistant mask; and filling up the groove with a second insulating film, and polishing the second insulating film by use of the first insulating film as a stopper film. Therefore, the method of the present invention includes the step of removing, by means of etching, the semiconductor layer positioned in upper and lower end portions of the groove. By use of the manufacturing method described above, a thermal stress applied to the semiconductor layer and electric field concentration on the upper end portion of the groove can be eased. Thus, occurrence of a crystal defect in the semiconductor layer in the lower end portion of the groove can be reduced.

Therefore, in the present invention, a third insulating film covers the upper surface of a boundary region between the second insulating film buried in the groove and the semiconductor layer. Thereafter, the silicon film is formed so as not to come into direct contact with the upper surface of the boundary region. By use of the manufacturing method described above, a thermal stress applied to the semiconductor layer and electric field concentration in the upper end portion of the groove can be eased.

Therefore, in the present invention, a base diffusion layer can be formed from a region away from the upper surface of a boundary region between the first insulating film buried in the groove and the semiconductor layer. By use of the manufacturing method described above, generation of a junction leak current between a collector and a base can be reduced.

Therefore, in the present invention, even if a crystal defect occurs from the end portion of the groove, the crystal defect can be avoided. By use of the manufacturing method described above, generation of the junction leak current between the collector and the base can be reduced.

In the present invention, an insulating film is selectively formed so as to cover at least an upper surface of the end portion of the groove which separates a collector diffusion layer from the base diffusion layer. Accordingly, a structure is formed, in which a silicon film electrically connected to the base diffusion layer never comes into direct contact with the end portion of the groove. By use of the manufacturing method described above, even if a crystal defect occurs from the end portion of the groove, generation of a junction leak current between a collector and a base can be reduced.

Moreover, in the present invention, a solid phase diffusion process is applied to impurities injected into a polycrystalline silicon film, and the base diffusion layer is formed. Thus, the insulating film covering the upper surface of the end portion of the groove makes it possible to form the base diffusion layer from a region away from the end portion of the groove. Moreover, the base diffusion layer and the end portion of the groove can be separated from each other. By use of the manufacturing method described above, even if a crystal defect occurs from the end portion of the groove, generation of a junction leak current between a collector and a base can be reduced.

Furthermore, in the present invention, after the groove is formed from the surface of the semiconductor layer and the semiconductor layer positioned in the end portion of the groove is etched, the groove is filled with an insulating film. By use of the manufacturing method described above, occurrence of a crystal defect from the end portion of the groove and the like can be suppressed, and generation of a junction leak current between a collector and a base can be reduced.

### BRIEF DESCRIPTION OF THE DRAWINGS

FIG. 1 is a cross-sectional view showing a method of manufacturing a semiconductor device according to an embodiment of the present invention.

FIG. 2 is a cross-sectional view showing the method of manufacturing a semiconductor device according to the embodiment of the present invention.

FIG. 3 is a cross-sectional view showing the method of manufacturing a semiconductor device according to the embodiment of the present invention.

FIG. 4 is a cross-sectional view showing the method of manufacturing a semiconductor device according to the embodiment of the present invention.

FIG. 5 is a cross-sectional view showing the method of manufacturing a semiconductor device according to the embodiment of the present invention.

FIG. 6 is a cross-sectional view showing the method of manufacturing a semiconductor device according to the embodiment of the present invention.

FIG. 7 is a cross-sectional view showing the method of manufacturing a semiconductor device according to the embodiment of the present invention.

FIG. 8 is a cross-sectional view showing the method of manufacturing a semiconductor device according to the embodiment of the present invention.

FIG. 9 is a cross-sectional view showing the method of manufacturing a semiconductor device according to the embodiment of the present invention.

FIG. 10 is a cross-sectional view showing the method of manufacturing a semiconductor device according to the embodiment of the present invention.

FIG. 11 is a cross-sectional view showing the method of manufacturing a semiconductor device according to the embodiment of the present invention.

FIG. 12 is a cross-sectional view showing the method of manufacturing a semiconductor device according to the embodiment of the present invention.

### DESCRIPTION OF THE PREFERRED EMBODIMENTS

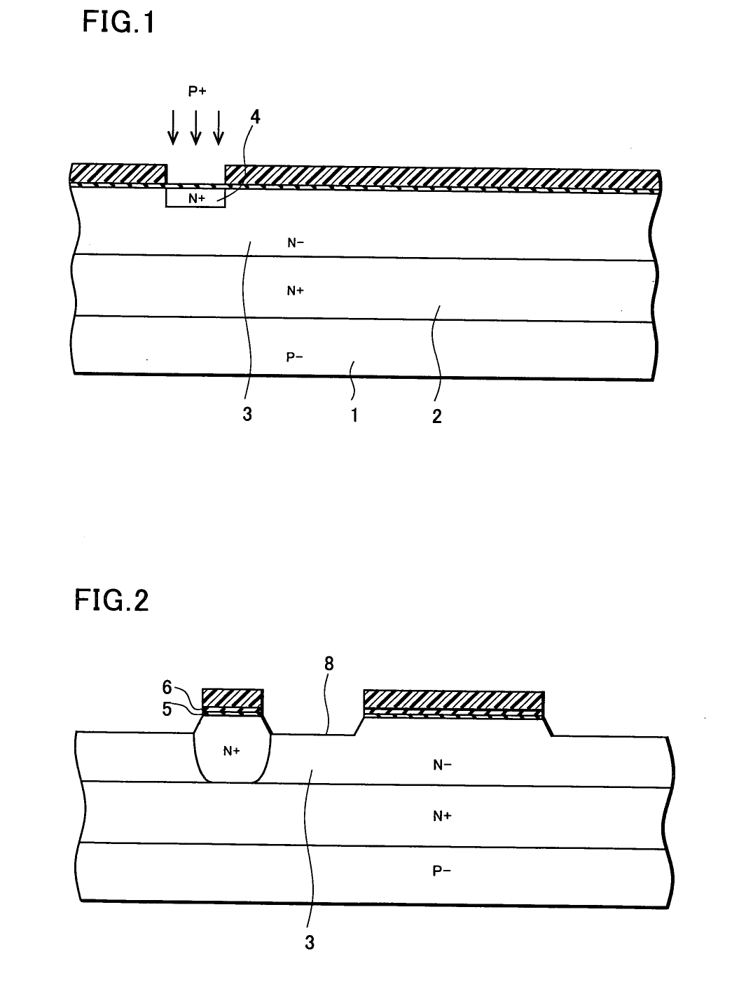

With reference to FIGS. 1 to 12, a method of manufacturing a semiconductor device according to an embodiment of the present invention will be described in detail below.

FIGS. 1 to 12 are cross-sectional views showing the method of manufacturing a semiconductor device according to this embodiment. Note that, in the following description, the case where an NPN-type transistor is formed, for example, in one of element formation regions divided by an isolation region will be described. However, the embodiment of the present invention is not limited to the case described above. For example, a semiconductor integrated circuit device may be formed by forming an N-channel MOS transistor, a P-channel MOS transistor, a vertical PNP transistor and the like in the other element formation regions.

First, as shown in FIG. 1, a P-type single crystal silicon substrate 1 is prepared. By use of a heretofore known photolithography technology, an N-type buried diffusion layer 2 is formed on a surface of the substrate 1. Thereafter, the substrate 1 is placed on a susceptor of an epitaxial growth apparatus. Subsequently, the substrate 1 is heated up to about 1200° C., for example, by lamp heating, and SiHCl₃ gas and H₂ gas are introduced into a reaction tube. Thus, an epitaxial layer 3 having a specific resistance of 0.1 to 2.0 Ω·cm and a thickness of about 0.5 to 1.5 μm is grown on the substrate 1.

Thereafter, a silicon oxide film is formed on the epitaxial layer 3. By use of the heretofore known photolithography technology, a photoresist is formed as a selective mask, the photoresist having an opening provided in a portion where an N-type diffusion region 4 is formed. Thereafter, ion implantation of N-type impurities, for example, phosphorus (P) is performed by an introduction amount of 1.0×10¹⁴ to 1.0×10¹⁶/cm² at an acceleration voltage of 80 to 120 keV. Subsequently, the photoresist is removed, and the impurities subjected to ion implantation are diffused.

Note that the substrate 1 and the epitaxial layer 3 in this embodiment correspond to a “semiconductor layer” of the present invention. Although the case where one epitaxial layer 3 is formed on the substrate 1 is described in this embodiment, the present invention is not limited to this case. For example, as the “semiconductor layer” of the present invention, only the substrate may be used, or a plurality of epitaxial layers may be laminated on the substrate. Moreover, the substrate may be an N-type single crystal silicon substrate or a compound semiconductor substrate. Furthermore, the N-type diffusion region 4 in this embodiment corresponds to a “collector diffusion layer” of the present invention.

Next, as shown in FIG. 2, a silicon oxide film 5 is formed on the epitaxial layer 3, and a silicon nitride film 6 is formed on the silicon oxide film 5. Thereafter, by use of the heretofore known photolithography technology, a photoresist is formed as a selective mask, the photoresist having an opening provided in a portion where a groove 8 is formed. After the silicon oxide film 5 and the silicon nitride film 6 are removed, about 5000 Å of the epitaxial layer 3 is removed by means of dry etching. The groove 8 is formed in the surface of the epitaxial layer 3.

Note that the groove 8 in this embodiment corresponds to a “groove” of the present invention. Meanwhile, the “groove” of the present invention may be formed by use of an arbitrary manufacturing method as long as the groove has a concave structure with respect to the surface of the epitaxial layer 3. Moreover, the silicon oxide film 5 and the silicon nitride film 6 in this embodiment correspond to a “first insulating film” of the present invention. The “first insulating film” of the present invention may be a film which can be utilized for formation of the groove 8 and for polishing by use of a CMP method.

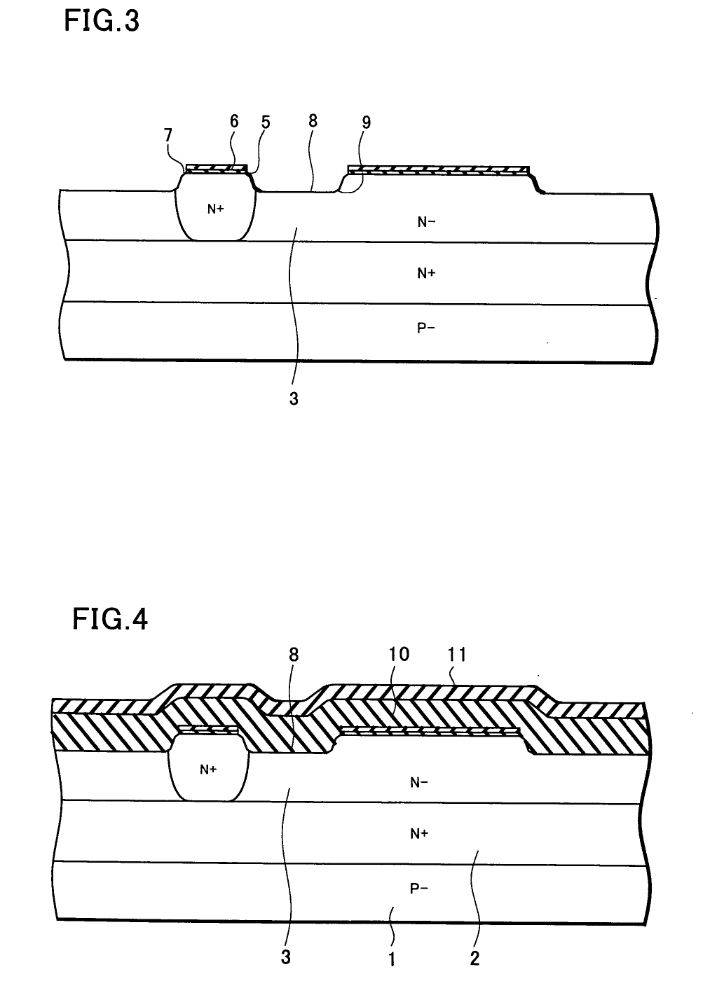

Next, as shown in FIG. 3, after the photoresist is removed, the silicon oxide film 5 and the silicon nitride film 6 are partially removed so as to expose an upper end portion 7 of the groove 8. Thereafter, by using the silicon nitride film 6 as an etching mask, for example, isotropic dry etching is performed. By this etching step, the epitaxial layer 3 positioned in the upper end portion 7 and a lower end portion 9 of the groove 8 is removed. Here, the upper and lower end portions 7 and 9 of the groove 8 have more obtuse-angled shapes compared to those before the etching. Practically, the upper and lower end portions 7 and 9 of the groove 8 have round shapes.

Specifically, in this embodiment, etching is performed, instead of a thermal oxidation method, to remove the epitaxial layer 3 positioned in the upper and lower end portions 7 and 9 of the groove 8. Thus, the N-type buried diffusion layer 2 can be prevented from being swollen upward or downward more than necessary. Note that the thermal oxidation method may be used as long as withstand pressure characteristics are not affected by upward swelling of the N-type buried diffusion layer 2. Moreover, by the etching step described above, an etching damage caused during formation of the groove 8 can also be removed.

Next, as shown in FIG. 4, by use of a high density plasma CVD (HDP CVD) method, an NSG (non-doped-silicate glass) film 10 is deposited on the epitaxial layer 3. In this event, for example, about 6000 Å of the NSG film 10 is deposited so as to fill up the groove 8.

By use of a low pressure CVD method, an HTO (high temperature oxide) film 11 is deposited on the NSG film 10 under a temperature condition of about 800° C. In this event, the HTO film 11 is deposited to have a thickness in a range of 3000 Å to 5000 Å, for example. Moreover, the HTO film 11 is a film having a better step coverage than the NSG film 10. Meanwhile, the NSG film 10 has a better filling property than the HTO film 11, and is used for filling up the groove 8 as described above.

Note that the NSG film 10 and the HTO film 11 in this embodiment correspond to a “second insulating film” of the present invention. The “second insulating film” of the present invention may be a film which fills up the groove 8. Moreover, as the “second insulating film” of the present invention, at least only the NSG film 10 may be used.

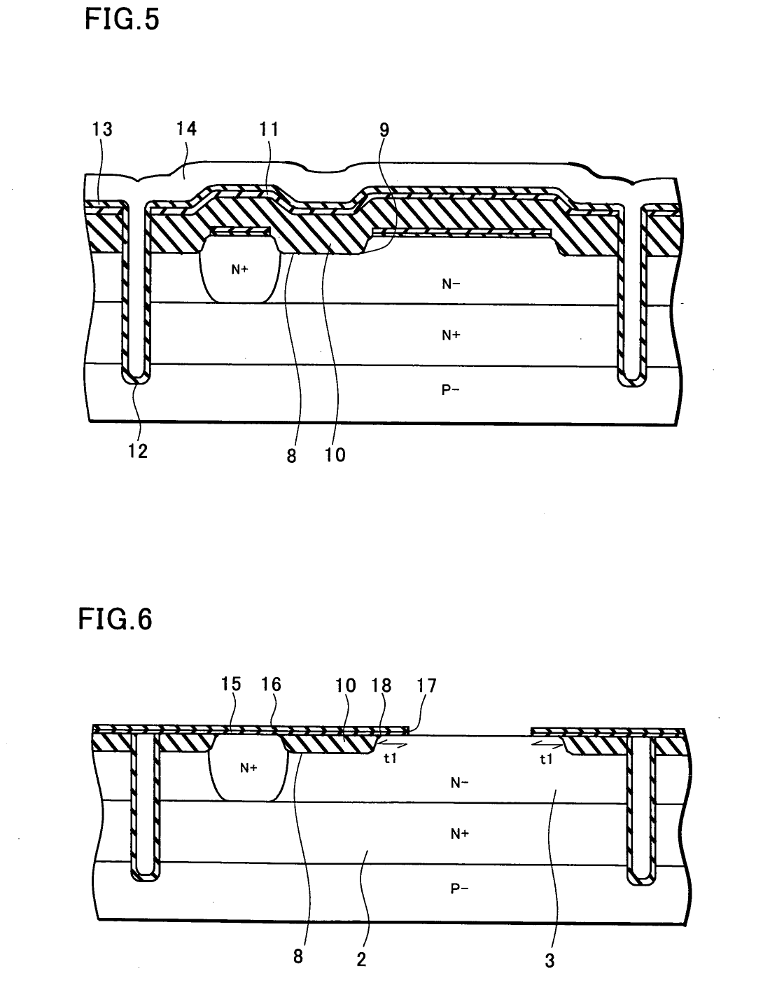

Next, as shown in FIG. 5, by use of the heretofore known photolithography technology, a trench 12 is formed by means of drying etching from an upper surface of the HTO film 11. Here, the trench 12 is formed to have a depth of about 6 μm, for example. Note that, the HTO film 11 is also removed from the surface thereof in the step of forming the trench 12, and the thickness of the HTO film 11 is also reduced after forming the trench 12. Here, the reason why the HTO film 11 is deposited to have the thickness within the range described above is because a problem of etching failure may occur if the HTO film 11 is thinner than 3000 Å. Meanwhile, if the HTO film 11 is thicker than 5000 Å, it may become difficult to pattern the NSG film 10 and the HTO film 11.

Thereafter, in the trench 12 and on the HTO film 11, an HTO film 13 is deposited under a temperature condition of about 800° C. by use of the low pressure CVD method. The HTO film 13 is deposited to have a thickness of about 3000 Å, and a part of the trench 12 is filled up from an inner wall of the trench 12. Thereafter, on the HTO film 13, a polycrystalline silicon film 14 is deposited by use of a CVD method. The polycrystalline silicon film 14 is deposited to have a thickness of about 8000 Å, and inside of the trench 12 is completely filled up with the polycrystalline silicon film 14. In this embodiment, after the HTO film 13 is buried in the trench 12, the polycrystalline silicon film 14 is buried therein. Accordingly, an amount of the polycrystalline silicon film 14 deposited on the epitaxial layer 3 can be reduced. Moreover, in the subsequent step using the CMP method, an amount of the polycrystalline silicon film 14 to be polished can be reduced, and the time spent for the expensive CMP method can be shortened.

Next, as shown in FIG. 6, by use of the CMP method using the silicon nitride film 6 as a stopper film, the NSG film 10, the HTO films 11 and 13, and the polycrystalline silicon film 14 are polished and at least partially removed. By this step, obtained is a structure in which the groove 8 is filled up with the NSG film 10 and the trench 12 is filled up with the HTO film 13 and the polycrystalline silicon film 14. After the silicon nitride film 6 is removed by using phosphoric acid of about 160° C., the silicon oxide film 5 is removed by using buffered hydrofluoric acid (BHF).

Subsequently, after a silicon oxide film 15 is deposited on the epitaxial layer 3 by use of the CVD method, a TEOS (tetra-ethyl-ortho-silicate) film 16 is deposited by use of the CVD method so as to cover the silicon oxide film 15. In this event, although not shown in FIG. 6, a plurality of element formation regions are formed by use of isolation regions on the same substrate 1, and a MOS transistor is formed in one of the element formation regions. Moreover, the silicon oxide film 15 is also used as a silicon oxide film formed as a protective film for a gate electrode of the MOS transistor. As described above, the silicon oxide film 15 and the TEOS film 16 are deposited by use of the CVD method. Thus, the N-type buried diffusion layer 2 can be prevented from being swollen upward or downward more than necessary in a heat environment due to the CVD method.

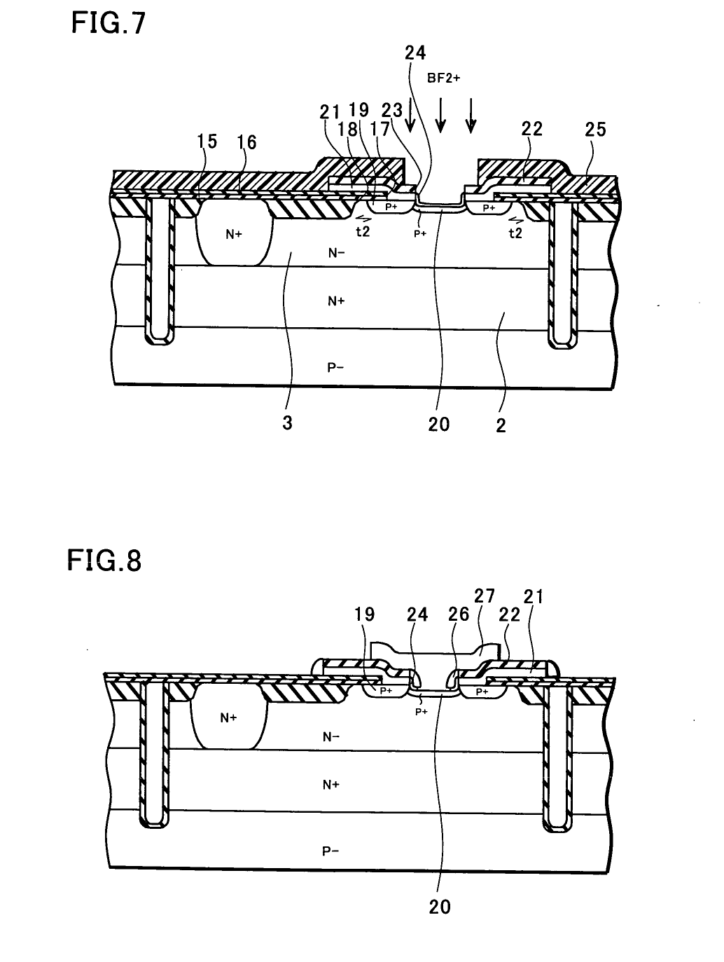

Note that the silicon oxide film 15 is not necessarily limited to the one deposited by use of the CVD method. The silicon oxide film 15 may be formed by use of the thermal oxidation method as long as the withstand pressure characteristics are not affected by upward swelling of the N-type buried diffusion layer 2. Moreover, the silicon oxide film 15 and the TEOS film 16 in this embodiment correspond to a “third insulating film” of the present invention. The “third insulating film” of the present invention may be a film which separates an upper end portion 18 (see FIG. 7) of the groove 8 from a base extraction electrode 21 (see FIG. 7).

Next, the silicon oxide film 15 and the TEOS film 16 are selectively removed so as to form an opening 17 in formation regions of an external base region 19 (see FIG. 7) and an active base region 20 (see FIG. 7) of an NPN-type transistor. As shown in FIG. 6, the opening 17 is formed to have a fixed distance t1 from the upper end portion 18 of the groove 8. Here, the upper end portion 18 means an upper end portion newly formed by etching and removing the upper end portion 7 of the groove as described above with reference to FIG. 2. Moreover, the upper end portion 18 means a boundary region of the epitaxial layer 3 coming in contact with the silicon oxide film 15. By use of the structure described above, the base extraction electrode 21 (see FIG. 7), which is formed on the TEOS film 16, and the upper end portion 18 of the groove 8 can be prevented from coming into contact with each other. Moreover, even if a crystal defect is caused in the epitaxial layer 3 from the upper end portion 18 of the groove 8, generation of a junction leak current between a collector and a base can be reduced through the crystal defect.

Next, as shown in FIG. 7, an amorphous silicon (a-Si) film is deposited to have a thickness of about 2000 Å on the epitaxial layer 3. Thereafter, on approximately the entire surface, ion implantation of P-type impurities, for example, boron fluoride (BF₂) is performed. Here, the impurities may be previously mixed with a-Si formation gas (gas made of H₂ and silicon, for example, silane) or may be deposited. Note that, in this embodiment, the a-Si film is used as a diffusion source and is utilized as the base extraction electrode 21. Thus, it is applicable to perform ion implantation capable of accurately performing control of a resistance value and concentration control of the external base region 19.

Thereafter, a TEOS film 22 is deposited to have a thickness of about 2000 Å by use of a plasma CVD method so as to cover the a-Si film. Here, the TEOS film 22 is deposited at a low temperature so as not to convert the a-Si film into Poly-Si. Moreover, the a-Si film is maintained in the a-Si state until the next etching step is finished.

Next, by use of the heretofore known photolithography technology, the a-Si film and the TEOS film 22 are selectively removed by means of etching so as to form an opening 23 in the formation region of the active base region 20. Accordingly, the patterned a-Si film is utilized as the base extraction electrode 21.

Here, in this embodiment, since the a-Si film is patterned without being converted into Poly-Si, surfaces of the base extraction electrode 21 and the active base region 20 are made smooth. Specifically, since there are no irregularities formed on the surface where the active base region 20 is formed, the active base region 20 has an approximately uniform depth of diffusion throughout the region. Moreover, since there are no irregularities on a sidewall of the base extraction electrode 21, there will be no influence on shapes of a silicon oxide film 24 and a spacer 26 (see FIG. 8), which are grown in the subsequent step.

Next, the silicon oxide film 24 is formed to have a thickness of about 100 to 200 Å on the sidewall of the base extraction electrode 21 and on the epitaxial layer 3. Thereafter, impurities in the base extraction electrode 21 are diffused by use of solid phase diffusion process into the epitaxial layer 3 to form the external base region 19. In this event, as described above, the region where the base extraction electrode 21 comes into contact with the epitaxial layer 3 has the fixed distance t1 from the upper end portion 18 of the groove 8. Meanwhile, the external base region 19 is formed so as to have a distance t2 from the upper end portion 18 of the groove 8. Specifically, in this embodiment, the opening 17 is formed in the silicon oxide film 15 and the TEOS film 16 and the solid phase diffusion process is used so as to secure the fixed distance t1. By use of the manufacturing method described above, the external base region 19 can be formed with more positional accuracy compared to those by use of a manufacturing method by which impurities are diffused after being subjected to ion implantation in the epitaxial layer 3.

Thereafter, by use of the heretofore known photolithography technology, a photoresist 25 is formed as a selective mask, which has an opening provided in a portion where the active base region 20 is to be formed. Subsequently, through the silicon oxide film 24, ion implantation of P-type impurities, for example, boron fluoride (BF₂) is performed by an introduction amount of 1.0×10¹² to 1.0×10¹⁴/cm² at an acceleration voltage of 10 to 30 keV. Thereafter, the photoresist 25 is removed, and the impurities subjected to ion implantation are diffused. Here, since a connection region on the surface of the epitaxial layer 3 is maintained to be flat without irregularities, a contact resistance can be reduced. Note that the external base region 19 in this embodiment corresponds to a “base diffusion layer” of the present invention. However, as described above, the external base region 19 and the active base region 20 form a base region of this embodiment.

Next, as shown in FIG. 8, the spacer 26 is formed on the sidewalls of the base extraction electrode 21 and the TEOS film 22 corresponding to the active base region 20. In this event, the spacer 26 is formed of an a-Si film or a Poly-Si film by means of anisotropic etching. Thereafter, the silicon oxide film 24 on the surface of the active base region 20 is removed by means of wet etching, for example.

On a surface including the exposed upper surface of the active base region 20, a silicon film made of Poly-Si or a-Si is deposited. In consideration of a resistance value of an emitter extraction electrode and an impurity concentration in an emitter region, the silicon film is subjected to ion implantation of N-type impurities, for example, arsenic (As) by an introduction amount of 1.0×10¹⁴ to 1.0×10¹⁶/cm² at an acceleration voltage of 80 to 120 keV. Thereafter, by use of the heretofore known photolithography technology, the silicon film is selectively removed by means of etching to form an emitter extraction electrode 27. Here, the base extraction electrode 21 and the emitter extraction electrode 27 are insulated from each other by the TEOS film 22 and the silicon oxide film 24.

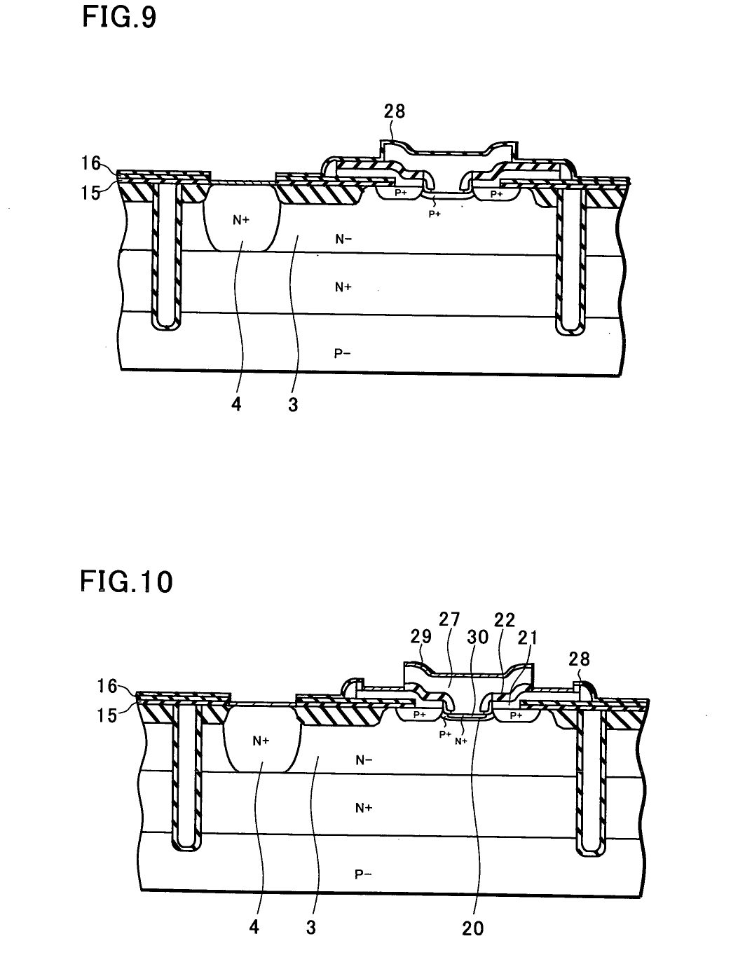

Next, as shown in FIG. 9, a TEOS film 28 is deposited on the epitaxial layer 3 by use of the low pressure CVD method, for example. Thereafter, by use of the heretofore known photolithography technology, the silicon oxide film 15 and the TEOS films 16 and 28 are selectively removed by means of dry etching so as to expose the N-type diffusion region 4. In this event, etching conditions can be set so as to expose only the N-type diffusion region 4. Thus, the risk of over-etching the surface of the epitaxial layer 3 can be significantly reduced.

Next, as shown in FIG. 10, by use of the heretofore known photolithography technology, the TEOS films 16 and 28 are selectively removed by means of dry etching so as to expose a part of the base extraction electrode 21. In this event, etching conditions can be set by considering only the thicknesses of the TEOS films 16 and 28 deposited on the base extraction electrode 21. Thus, the risk of over-etching the surface of the base extraction electrode 21 can be significantly reduced.

Thereafter, the TEOS film 28 on the upper surface and sidewall of the emitter extraction electrode 27 is removed. Subsequently, a cobalt layer is selectively formed on the exposed upper surfaces of the N-type diffusion region 4, the base extraction electrode 21 and the emitter extraction electrode 27. The cobalt layer is removed after annealed. In a heat environment during annealing, a cobalt silicide (CoSi₂) film 29 is formed on the exposed surfaces of the N-type diffusion region 4, the base extraction electrode 21 and the emitter extraction electrode 27.

Note that, in the heat environment during annealing of the cobalt layer deposited, impurities injected into and diffused in the emitter extraction electrode 27 are diffused by use of a solid phase diffusion process from the emitter extraction electrode 27. Thus, an N-type emitter region 30 is formed on the surface of the active base region 20. Note that the N-type emitter region 30 in this embodiment corresponds to an “emitter diffusion layer” of the present invention.

Next, as shown in FIG. 11, a silicon nitride film (not shown) is deposited on the epitaxial layer 3 by use of the CVD method. Thereafter, liquid SOG (spin on glass) is applied to an upper surface of the silicon nitride film to form a SOG film 31. Subsequently, a TEOS film 32 is deposited on the SOG film 31 by use of the low pressure CVD method.

In order to secure a flat surface of the TEOS film 32, etching-back is carried out from the surface side of the substrate 1 by use of the CMP method. Thereafter, by use of the heretofore known photolithography technology, contact holes 33 to 35 are formed in the SOG film 31, the TEOS film 32 and the like by means of dry etching using CHF₃+O₂ gas, for example.

In this event, as shown in FIG. 11, the contact hole 33 for a collector electrode is the deepest, and the contact holes 33 to 35 are simultaneously formed under etching conditions for forming the contact hole 33. As described above, the cobalt silicide film 29 is formed on the surfaces of the N-type diffusion region 4, the base extraction electrode 21 and the emitter extraction electrode 27. The cobalt silicide film 29 is utilized as an etching stopper film in dry etching. As a result, even if the contact holes 33 to 35 are formed in the same step, particularly, the surfaces of the base extraction electrode 21 and the emitter extraction electrode 27 can be prevented from being over-etched. Thereafter, a barrier metal film 36 is formed on an exposed surface of the cobalt silicide film 29, on sidewalls of the contact holes 33 to 35 and on the surface of the TEOS film 32.

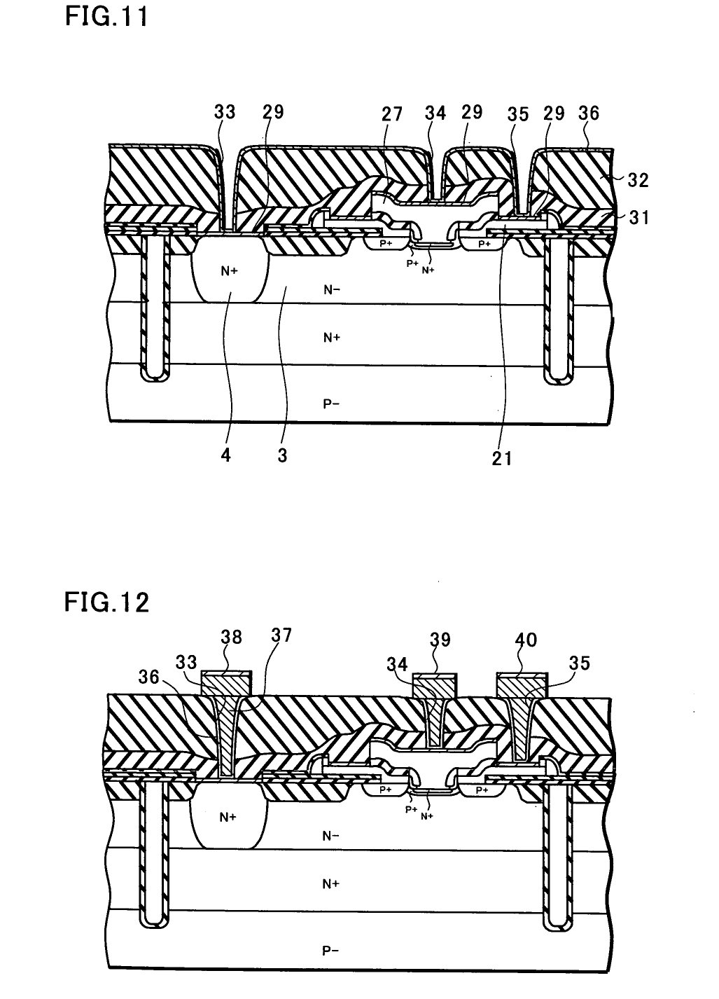

Lastly, as shown in FIG. 12, the contact holes 33 to 35 are filled with a tungsten (W) film 37. Thereafter, by use of the CVD method, an aluminum-copper (AlCu) film and a barrier metal film are deposited on the W film 37 and the barrier metal film 36. Subsequently, by use of the heretofore known photolithography technology, the AlCu film and the barrier metal film are selectively removed to form a collector electrode 38, an emitter electrode 39 and a base electrode 40.

As described above, in this embodiment, the method includes the step of forming the silicon oxide film 15 and the TEOS film on the epitaxial layer 3 before the step of forming the base extraction electrode 21. By use of the manufacturing method described above, it is possible to realize the structure in which the upper end portion 18 of the groove 8 and the base extraction electrode 21 never come into direct contact with each other. Thus, even in the case where a crystal defect is caused in the upper end portion 18 of the groove 8 by a thermal stress attributable to a heat treatment step after formation of the groove 8, generation of the junction leak current between the collector and the base due to the crystal defect can be suppressed.

Moreover, by utilizing the base extraction electrode 21 to form the external base region 19 by a solid phase diffusion process, there is secured the distance t2 between the external base region 19 and the upper end portion 18 of the groove 8. Specifically, even if a crystal defect is caused in the upper end portion 18 of the groove 8, the external base region 19 can be formed so as to avoid the crystal defect.

Furthermore, after the N-type buried diffusion layer 2 is formed, a high-temperature processing step such as the thermal oxidation method, for example, is reduced. Accordingly, the N-type buried diffusion layer 2 is prevented from being swollen upward or downward more than necessary by heat treatment in the subsequent step. By use of the manufacturing method described above, the thickness of the epitaxial layer 3 can be reduced. Thus, a process load can be reduced. Moreover, by reducing the thickness of the epitaxial layer 3, the depth of the trench 12 forming the isolation region can be reduced. Thus, the process load can be reduced.

Moreover, the cobalt silicide film 29 formed on the surfaces of the N-type diffusion region 4, the base extraction electrode 21 and the emitter extraction electrode 27 is used as the etching stopper film in formation of the contact holes 33 to 35. Moreover, in consideration of mask misalignment, the cobalt silicide film 29 is formed to be wider than a contact hole region. Particularly, since a current also flows in a horizontal direction relative to the substrate 1 in the base extraction electrode 21, resistance reduction can be realized by the cobalt silicide film 29.

Moreover, in the semiconductor device manufactured by use of the manufacturing method described above, even if the thickness of the epitaxial layer 3 is reduced, a length from the bottom of the base region to the upper surface of the collector region can be secured. Accordingly, desired withstand pressure characteristics can be obtained. Furthermore, by reducing the thickness of the epitaxial layer 3, the resistance value in the collector region is lowered. Thus, high-frequency characteristics can also be improved. Meanwhile, by reducing downward swelling of the N-type buried diffusion layer 2, a parasitic capacity between the semiconductor substrate and the collector region is reduced. Thus, the high-frequency characteristics can be maintained.

Note that, in this embodiment, the description was given of the case where the CVD method is used, for example, as a vapor phase growth method. However, the method is not limited to the CVD method. Besides the CVD method, a physical vapor phase growth method such as vapor deposition may be used. Specifically, any method may be used as long as the method can significantly reduce the step of subjecting the semiconductor substrate to high-temperature heat treatment such as the thermal oxidation method. Moreover, although the description was given of the case where the cobalt silicide film is used as silicide, the embodiment of the present invention is not limited to this case. The effects described above can also be obtained by use of a molybdenum silicide (MoSi₂) film, a tungsten silicide (WSi₂) film, a titanium silicide (TiSi₂) film, a nickel silicide (NiSi₂) film, a platinum silicide (PtSi₂) film or the like, for example, in place of the cobalt silicide film. Besides the above, various changes can be made without departing from the scope of the present invention.

What is claimed is:

1. A method of manufacturing a semiconductor device, comprising the steps of:
forming a first insulating film on a semiconductor layer, the first insulating film having a first opening provided in a desired region, and forming a groove in the semiconductor layer through the first opening;
partially removing the first insulating film so as to expose an upper end portion of the semiconductor layer from a region adjacent to the groove;
etching the semiconductor layer so as to remove the upper end portion of the semiconductor layer by use of the first insulating film as an etching resistant mask; and
filling up the groove with a second insulating film, and polishing the second insulating film by use of the first insulating film as a stopper film.

2. The method of manufacturing a semiconductor device according to claim 1, further comprising the step of:
depositing a third insulating film on the semiconductor layer, selectively removing the third insulating film so as to cover at least an upper surface of a boundary region between the second insulating film buried in the groove and the semiconductor layer, and selectively forming a silicon film on the semiconductor layer.

3. The method of manufacturing a semiconductor device according to claim 2, further comprising the step of:
forming a collector diffusion layer, a base diffusion layer and an emitter diffusion layer from a surface of the semiconductor layer, and forming a transistor,
wherein the base diffusion layer is formed in such a manner that, after the third insulating film is removed so as to provide a second opening in a region where the base diffusion layer is to be formed, impurities injected into the silicon film are diffused by use of a solid phase diffusion process from the silicon film positioned in the second opening into the semiconductor layer.

4. The method of manufacturing a semiconductor device according to claim 3, wherein the solid phase diffusion is performed so that the base diffusion layer is away from the boundary region.
